(19) United States
(12) Patent Application Publication
(10) Pub. No.: US 2025/0117551 A1
(43) Pub. Date: Apr. 10, 2025

(54) MACHINE LEARNING MODEL-BASED DETERMINATION OF POWER CONSUMPTION IN ADDRESSING APPLICATION REQUEST(S)

(71) Applicant: INTERNATIONAL BUSINESS MACHINES CORPORATION, Armonk, NY (US)

(72) Inventors: Fan Jing MENG, Beijing (CN); Hua YE, Beijing (CN); Wei DING, Beijing (CN); Cheng Fang WANG, Beijing (CN); Mai ZENG, Beijing (CN); Peng Hui JIANG, Beijing (CN)

(21) Appl. No.: 18/482,094

(22) Filed: Oct. 6, 2023

(51) Int. Cl. G06F 30/27

(52) U.S. Cl. CPC G06F 30/27

(57) ABSTRACT

A machine learning power consumption model and process are provided for determining power consumption of computing environment resources in handling requests of an application. The process includes training the machine learning power consumption model to estimate power consumption of computing environment resources in handling requests. The training uses a training dataset derived from historical request-related data, and the training dataset includes request-related data and resource power consumption data. In addition, the process includes analyzing the requests. The analyzing includes, for a particular request of the requests, obtaining a common pattern of resource use and collecting real-time trace metrics to facilitate allocating resource use to the particular request. In addition, the process includes using the machine learning power consumption model, the obtained common pattern, and the collected real-time trace metrics for the particular request in generating an estimate of the power consumption in addressing the particular request.

### BACKGROUND

This disclosure relates generally to the field of computing, and more particularly, to ascertaining resource power consumption in addressing application requests in a shared computing environment, such as requests in a database as a service (DBaaS) computing environment.

Database as a service (DBaaS), also known as a managed database service, is typically a cloud computing service that lets users access and use a cloud database system. Compared to deploying a database management system on-premises, database as a service offers a user certain financial, operational, and strategic benefits, such as, cost savings, ability to scale up or down as needed, less costly management, rapid development time to market, and added data and application security.

Sustainability is a rapidly growing area of focus, including in computing environments, such as data center environments and cloud-based computing environments. Current power consumption monitoring approaches typically focus on the infrastructure level (e.g., servers, network devices, storage, etc.), with physical sensors or software components being used to monitor power consumed by devices or components at the infrastructure level.

### SUMMARY

Certain shortcomings of the prior art are overcome, and additional advantages are provided herein through the provision of a computer-implemented method that includes training a machine learning power consumption model to estimate power consumption of computing environment resources in handling requests. The training uses a training dataset derived from historical request-related data, where the training dataset includes request-related data and resource power consumption data. In addition, the computer-implemented method includes analyzing the requests. The analyzing includes, for a particular request of the requests, obtaining a common pattern of resource use and collecting real-time trace metrics to facilitate allocating resource use to the particular request. In addition, the computer-implemented method includes using the machine learning power consumption model, the obtained common pattern and the collected real-time trace metrics for the particular request in generating an estimate of power consumption in addressing the particular request.

Computer systems and computer program products relating to one or more aspects are also described and claimed herein. Further, services relating to one or more aspects are also described and may be claimed herein.

Additional features and advantages are realized through the techniques described herein. Other embodiments and aspects are described in detail herein and are considered a part of the claimed aspects.

### BRIEF DESCRIPTION OF THE DRAWINGS

One or more aspects are particularly pointed out and distinctly claimed as examples in the claims at the conclusion of the specification. The foregoing and objects, features, and advantages of one or more aspects are apparent from the following detailed description taken in conjunction with the accompanying drawings in which:

FIG. 1 depicts one example of a computing environment to include and/or use one or more aspects of the present disclosure;

FIG. 2 depicts one embodiment of a computer program product with an application power consumption determination module, in accordance with one or more aspects of the present disclosure;

FIG. 3 depicts one embodiment of an application power consumption determination workflow, in accordance with one or more aspects of the present disclosure;

FIG. 4 depicts one detailed embodiment of an application power consumption determination system, in accordance with one or more aspects of the present disclosure;

FIG. 5A depicts one embodiment of an application tracing graph build process, in accordance with one or more aspects of the present disclosure;

FIG. 5B depicts an exemplary embodiment of a database tracing graph, in accordance with one or more aspects of the present disclosure;

FIG. 5C illustrates one embodiment of a call graph reflecting flow of interactions and dependencies among components involved in processing a database request, in accordance with one or more aspects of the present disclosure;

FIG. 6A illustrates one embodiment of a machine learning power consumption model training process, in accordance with one or more aspects of the present disclosure;

FIG. 6B depicts one example of an exemplary training dataset for training a machine learning power consumption model to estimate power consumption of resources in handling application requests, in accordance with one or more aspects of the present disclosure;

FIG. 7 illustrates an exemplary machine learning training system that can be utilized to train a machine learning power consumption model to estimate power consumption of resources in handling requests, in accordance with one or more aspects of the present disclosure;

FIG. 8A depicts one workflow embodiment of a database request analyzer of the application power consumption determination system of FIG. 4, in accordance with one or more aspects of the present disclosure;

FIG. 8B depicts one exemplary embodiment of collected database-specific metrics relevant to energy consumption, in accordance with one or more aspects of the present disclosure;

FIG. 9 illustrates one example of power consumption estimations in addressing particular database requests, in accordance with one or more aspects of the present disclosure;

FIG. 10 is a further example of a computing environment to include and/or use one or more aspects of the present disclosure; and

FIG. 11 depicts another embodiment of an application power consumption determination workflow of an application power consumption determination module or system such as depicted in FIGS. 1-10, in accordance with one or more aspects of the present disclosure.

### DETAILED DESCRIPTION

The accompanying figures, which are incorporated in and form a part of this specification, further illustrate the present disclosure and, together with this detailed description of the disclosure, serve to explain aspects of the present disclosure. Note in this regard that descriptions of well-known systems, devices, processing techniques, etc., are omitted so as to not unnecessarily obscure the disclosure in detail. It should be understood, however, that the detailed description and specific example(s), while indicating aspects of the disclosure, are given by way of illustration only, and not limitation. Various substitutions, modifications, additions, and/or other arrangements, within the spirit or scope of the underlying inventive concepts will be apparent to those skilled in the art from this disclosure. Note further that numerous inventive aspects or features are disclosed herein, and unless inconsistent, each disclosed aspect or feature is combinable with any other disclosed aspect or feature as desired for a particular application of the concepts disclosed.

Note also that illustrative embodiments are described below using specific code, designs, architectures, protocols, layouts, schematics, systems, or tools only as examples, and not by way of limitation. Furthermore, the illustrative embodiments are described in certain instances using particular software, hardware, tools, and/or data processing environments only as example for clarity of description. The illustrative embodiments can be used in conjunction with other comparable or similarly purposed structures, systems, applications, architectures, etc. One or more aspects of an illustrative embodiment can be implemented in software, hardware, or a combination thereof.

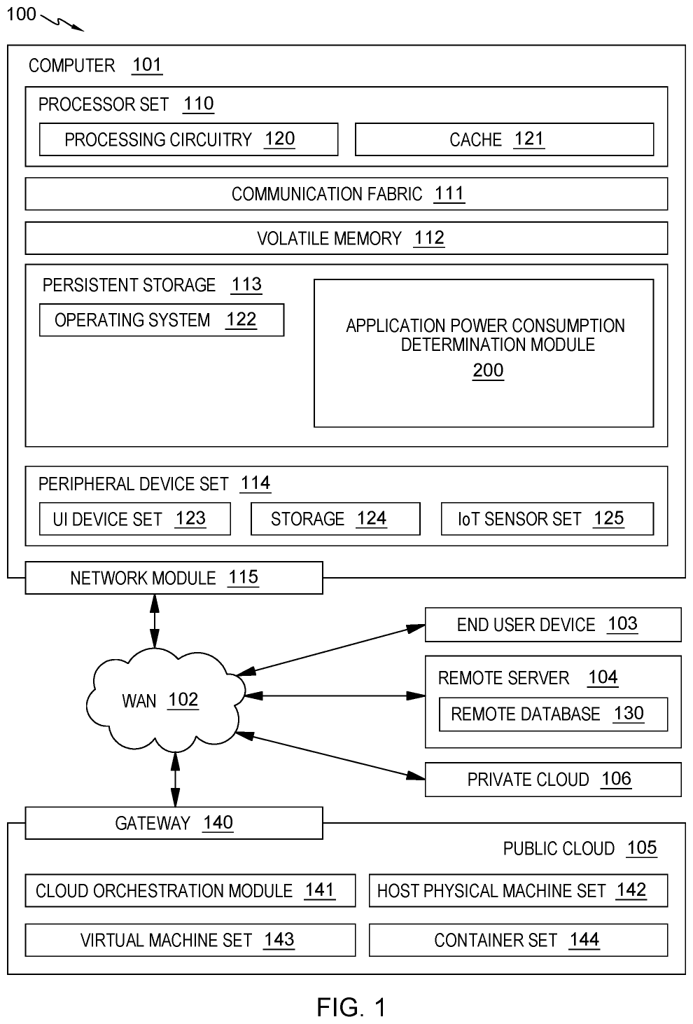

As understood by one skilled in the art, program code, as referred to in this application, can include software and/or hardware. For example, program code in certain embodiments of the present disclosure can utilize a software-based implementation of the functions described, while other embodiments can include fixed function hardware. Certain embodiments combine both types of program code. Examples of program code, also referred to as one or more programs, are depicted in FIG. 1, including operating system 122 and application power consumption determination module 200, which are stored in persistent storage 113.

One or more aspects of the present disclosure are incorporated in, performed and/or used by a computing environment. As examples, the computing environment can be of various architectures and of various types, including, but not limited to: personal computing, client-server, distributed, virtual, emulated, partitioned, non-partitioned, cloud-based, quantum, grid, time-sharing, clustered, peer-to-peer, mobile, having one node or multiple nodes, having one processor or multiple processors, and/or any other type of environment and/or configuration, etc., that is capable of executing a process (or multiple processes) that, e.g., perform application power consumption determination processing, such as disclosed herein. Aspects of the present disclosure are not limited to a particular architecture or environment.

Prior to further describing detailed embodiments of the present disclosure, an example of a computing environment to include and/or use one or more aspects of the present disclosure is discussed below with reference to FIG. 1.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as application power consumption determination module block 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

Communication fabric 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 200 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

The computing environment described above is only one example of a computing environment to incorporate, perform and/or use one or more aspects of the present disclosure. Other examples are possible. Further, in one or more embodiments, one or more of the components/modules of FIG. 1 need not be included in the computing environment and/or are not used for one or more aspects of the present disclosure. Further, in one or more embodiments, additional and/or other components/modules can be used. Other variations are possible.

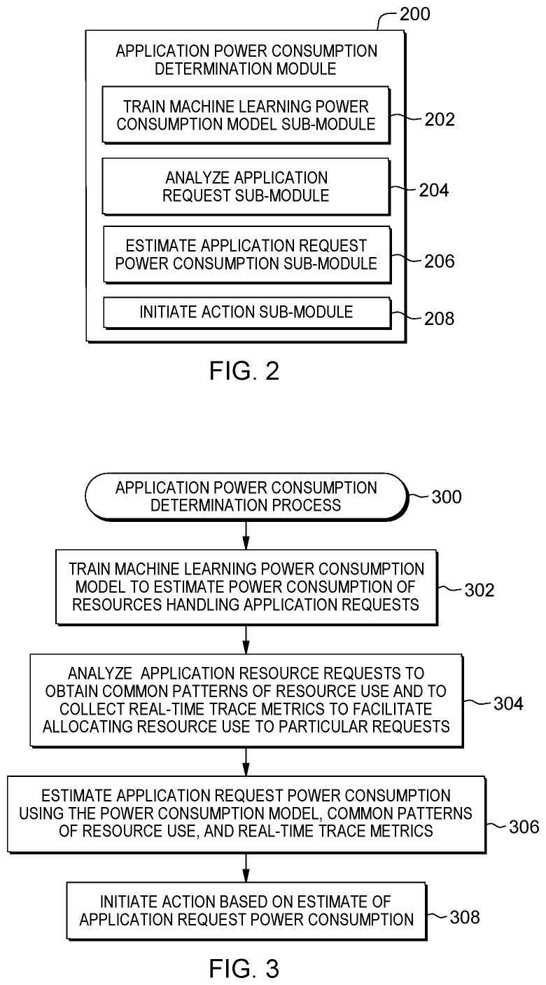

By way of example, one or more embodiments of an application power consumption determination module and process are described initially with reference to FIGS. 2-3. FIG. 2 depicts one embodiment of application power consumption determination module 200 that includes code or instructions to perform application power consumption determination processing, in accordance with one or more aspects of the present disclosure, and FIG. 3 depicts one embodiment of an application power consumption determination process, in accordance with one or more aspects of the present disclosure.

Referring to FIGS. 1-2, application power consumption determination module 200 includes, in one example, various sub-modules used to perform processing, in accordance with one or more aspects of the present disclosure. The sub-modules are, e.g., computer-readable program code (e.g., instructions) and computer-readable media (e.g., persistent storge (e.g., persistent storage 113, such as a disk) and/or a cache (e.g., cache 121), as examples). The computer-readable media can be part of a computer program product and can be executed by and/or using one or more computers, such as computer(s) 101; processors, such as a processor of processor set 110; and/or processing circuitry, such as processing circuitry of processor set 110, etc.

As noted, FIG. 2 depicts one embodiment of an application power consumption determination module 200 which, in one or more embodiments, includes, or provides application power consumption determination processing in accordance with one or more aspects of the present disclosure. In the embodiment of FIG. 2, example sub-modules of application power consumption determination module 200 include a train machine learning power consumption model sub-module 202 to train a machine learning power consumption model to estimate power consumption of resources in handling requests of an application. The training uses, in one or more embodiments, a training dataset derived, at least in part, from historical request-related data, where the training dataset includes request-related data and resource power consumption data. In one or more embodiments, application power consumption determination module 200 further includes an analyze application request sub-module 204 to analyze requests. In one or more embodiments, the analyzing includes, for a particular request of the requests, obtaining a common pattern (or request pattern) of resource use for the request type, and collecting real-time trace metrics to facilitate allocating resource use to the particular request. Further, in one or more embodiments, the application power consumption determination module 200 further includes an estimate application request power consumption sub-module 206, which uses the machine learning power consumption model, the obtained common pattern, and the collected real-time trace metrics for the particular request in estimating power consumption in addressing the particular request of the application. In addition, in one or more embodiments, the application power consumption determination module 200 includes an initiate action sub-module 208 to, for instance, initiate one or more actions based on the estimated power consumption. The one or more actions can include, for instance, determining an estimated cost for performing the application request, providing the estimated power consumption and/or cost estimate to a user or a user system initiating one or more application requests, modifying one or more application requests based on the estimated request power consumption (e.g., to reduce power consumption), etc. Note that although various sub-modules are described herein, application power consumption determination module processing, such as disclosed, can use, or include, additional, fewer, and/or different sub-modules. A particular sub-module can include additional code, including code of other sub-modules, or less code. Further, additional and/or other sub-modules can be used. Many variations are possible.

Advantageously, application power consumption determination processing such as disclosed herein facilitates sustainability of a computing environment by providing visibility into energy consumption of one or more requests of an application within a shared computing environment, thereby allowing energy usage to be understood in real-time, and thus optimized, at the user or application level. By being able to estimate energy consumption at a request level, it is possible to manage energy consumption at the application level.

In one or more embodiments, the sub-modules are used, in accordance with one or more aspects of the present disclosure, to perform application power consumption determination processing. FIG. 3 depicts one example of an application power consumption determination process 300, such as disclosed herein. The process is executed, in one or more examples, by a computer (e.g., computer 101 (FIG. 1)), and/or a processor or processing circuitry (e.g., of processor set 110 of FIG. 1). In one example, code or instructions implementing the process, are part of a module, such as application power consumption determination module 200. In other examples, the code can be included in one or more other modules and/or in one or more sub-modules of the one or more other modules. Various options are available.

As one example, application power consumption determination process 300 executing on a computer (e.g., computer 101 of FIG. 1), a processor (e.g., a processor of processor set 110 of FIG. 1), and/or processing circuitry (e.g., processing circuitry of processor set 110), trains a machine learning power consumption model to estimate power consumption of computing environment resources in handling application requests 302. In one or more embodiments, the training uses a training dataset derived from historical request-related data, with the training dataset including request-related data and resource power consumption data. In one or more embodiments, application power consumption determination process 300 further analyzes application requests to obtain common patterns of resource use and to collect real-time trace metrics to facilitate allocating resource use of a computing environment to a particular request 304. In addition, application power consumption determination process 300 further estimates application power consumption of a particular application request using the power consumption model, a respective common pattern of resource use, and real-time trace metrics for the particular application 306. Based on the estimate of application request power consumption, one or more actions can be initiated 308, such as an action to provide a user or user system with a cost estimate for addressing the particular application request, a cost estimate for addressing a number of application requests, a request to modify one or more application requests based, for instance, on the estimated power consumption being excessive, etc.

As noted, sustainability is a rapidly growing area of focus for many organizations, including for computing environments, such as data center computing environments and cloud-based computing environments. Modern applications, such as artificial intelligence (AI), machine learning, blockchain, encryption processes, etc., and infrastructures (e.g., fifth generation (5G), Internet of Things (IoT), Industrial Internet of Things (IIoT), etc.), continue to consume more and more energy. The same is true for power consumption of many databases, such as a database as a service (DBaaS). Note that, as one embodiment, the computing environment is a shared computing environment, and is described herein as a database as a service (DBaaS) environment, by way of example. However, note also that the concepts disclosed apply to a broader scope of applications, including, for instance, cloud-native applications, web applications, IoT applications, AI applications, mobile applications, batch jobs, etc.

Users continue to seek efficient application observability or monitoring capabilities with key metrics, including for applications in environments such as shared computing environments. Determining energy-related metrics is important to achieving sustainability goals for many applications. Advantageously, the application power consumption determination module, process, and system disclosed herein allow for accurately attributing power consumption to different applications or different users to identified high energy consumers and to facilitate optimizing resource allocation accordingly. The ability to estimate energy consumption for different types of requests of an application described herein enables establishing, for instance, service level agreements (SLAs) that incorporate energy usage considerations. In addition, estimation and attribution of power consumption allows for better environmental sustainability management, and the accurate estimation and attribution of energy consumption provides transparency to users about their resource usage and associated costs. In one or more embodiments, requests of an application can be adjusted (e.g., reduced) based on the estimated energy consumption of the requests.

As noted, a database as a service (DBaaS) embodiment is described herein as one example only of the application power consumption determination process disclosed. As background, managing databases in a modern information technology (IT) landscape has become increasingly challenging due to a variety of factors. For instance, the number of databases and their associated objects (tables, indices, etc.) has grown exponentially. Databases now serve as backend computing for interactive services and components and require real-time data processing and response capabilities. Databases are frequently deployed in cloud environments or virtualized infrastructures, and this leads to additional layers of abstraction and management complexities. The presence of diverse database technologies, such as relational databases, NoSQL databases, and specialized datastores, creates a heterogeneous environment that demands expertise in managing different database systems simultaneously. When applications (e.g., applications, workloads, or services) run within shared environments in a DBaaS, accurately allocating energy consumption to specific applications or requests becomes challenging. The lack of visibility into individual energy consumption of requests within shared computing environments makes it difficult to track and optimize energy usage at the user or application (e.g., workload) level.

Current power consumption monitoring approaches typically focus on the infrastructure level (e.g., servers, network devices, storage, etc.), with physical sensors or software components being used to monitor power consumed by components at the infrastructure level. However, for a variety of applications, including, for instance, for database as a service (DBaaS) applications, there is no effective way to measure or determine application level energy consumption due to the complexity and diversity of the shared computing environment.

In one or more embodiments, computer-implemented methods, computer systems, and computer program products are disclosed herein, which facilitate determining power consumption at a request level within a shared computing environment, such as within a database as a service (DBaaS) application environment. In one or more implementations, the process includes training a machine learning power consumption model to estimate power consumption of computing environment resources in handling requests. The training uses a training dataset derived, at least in part, from historical request-related data, where the training dataset includes request-related data and resource power consumption data. In addition, the process includes analyzing the requests. The analyzing includes, for a particular request of the requests, obtaining a common pattern (i.e., a request pattern) of resource use, and collecting real-time trace metrics to facilitate allocating resource use to the particular request. Further, the process includes using the machine learning power consumption model, the obtained common pattern, and the collected real-time metrics for the particular request in estimating power consumption in addressing the particular request. Advantageously, the power (or energy) consumption determination process disclosed herein is outcome-oriented in that incoming requests (i.e., requests and/or calls) to applications (i.e., applications and/or workloads) are the starting point for determining or estimating power consumption in handling the requests. Further, the application power consumption determination process disclosed is tracing-based. For instance, in one or more embodiments, dynamic service tracing data and system call-stacks are considered in allocating power consumption of the shared components and/or platform to a particular application or application request. In addition, the power consumption determination process is machine-learning-enabled. By applying machine learning and/or deep learning, a power consumption model is trained (and periodically retrained) to estimate energy consumption for each type of request.

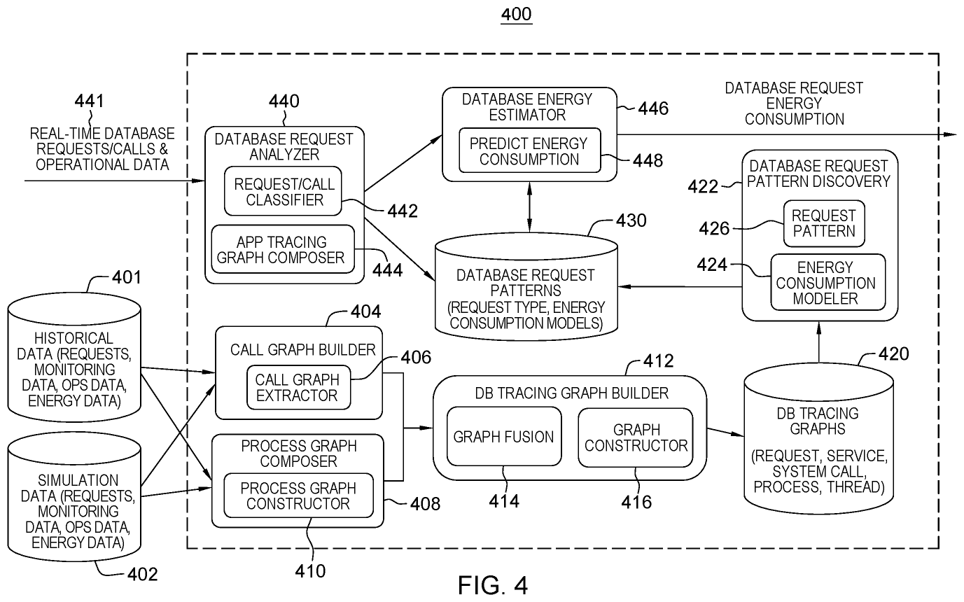

FIG. 4 depicts one detailed embodiment of an application power consumption determination system 400, in accordance with one or more aspects of the present disclosure. In one or more embodiments, application power consumption determination system 400 implements, and represents one detailed embodiment of, the application power consumption determination module and process described above in connection with FIGS. 1-3.

As noted, in one or more embodiments, the application power consumption determination system/process includes training a machine learning power consumption model to estimate power consumption of computing environment resources in handling requests of an application. In one or more embodiments, the system is based on patterns of resource use. Note that, as used herein, the term pattern is a generic term, and refers to a pattern of resource use that may not be expressed as a graph. As an example, in a database environment, there are typically create, read, update, and delete requests, which are lightweight requests, and query and replication requests, which are heavier processing requests. A graph outlines, for instance, resources (services, components, processes, threads, etc.) that have been used, and is expressed with nodes and edges, where adjacent nodes are connected with an edge. Call graphs, process graphs, and tracing graphs are also described below. In this context, common patterns (or request patterns) are recurring or common sequences or behaviors of incoming requests made as part of an application, such as to a database as a service (DBaaS) application. Call graphs represent hierarchical structures of function or method calls within a software application. In this context, a call graph shows how different components or services in the application (e.g., DBaaS system) interact with each other through function calls. A process graph illustrates the relationships and dependencies between different processes or threads within a software system, showing how they interact and exchange information. A tracing graph, as used herein, refers to a graph that captures the paths of execution and dataflow as requests traverse through, for instance, the DBaaS system. Tracking graphs can include details on how requests move between different components or services.

More particularly, FIG. 4 depicts one embodiment of an application power consumption determination system 400, which includes in part components (i.e., facilities, modules, etc.) for training a machine learning power consumption model to estimate power consumption of computing environment resources in handling requests, such as described herein. As illustrated, application power consumption determination system 400 includes a call graph builder 404, and a process graph composer 408. In one embodiment, call graph builder 404 includes a call graph extractor 406, and process graph composer 408 includes a process graph constructor 410. In one or more embodiments, call graph builder 404 is provided to build application call graphs (e.g., database service call graphs) based on application (including service) tracing data and system call stacks, and process graph composer 408 is configured to discover the processes (or threads) for the particular requests and request-dependent components or services (e.g., dependent database components and/or services). In one or more embodiments, call graph builder 404 and process graph composer 408 are program code components which receive or access a database 401 with historical data, and a database 402 with simulation data. The historical data includes request-related data including, for instance, requests, monitored data, operations data, energy consumed data, etc. Similarly, the simulation data includes simulated request-related data, including requests, monitored data, operations data, energy consumed data, etc., which relate to one or more requests of the application from which the call graph is being extracted, and/or the process graph is being constructed.

As illustrated in FIG. 4, the call graphs and process graphs are used by a database tracing graph builder 412, which includes a graph-fusion component 414 and a graph constructor 416, which operate to produce a tracing graph, and in particular, one or more database tracing graphs 420, in the example embodiment of a database as a service. As noted, database tracing graphs refer to graphs that capture the paths of execution and dataflow as requests traverse through the database system (in one example). The tracing graphs can include details on how a request moves between different components or services. Database tracing graph builder 412 builds the application trace and topology for each request (i.e., for each request or call) by, for instance, infusing system tracing data into the call graphs. In one or more embodiments, the database tracing graphs 420 are graphs that capture requests, service, system call, process, thread, etc., data related to a request. In one or more embodiments, DBaaS application tracing graphs are built based on collected data, including the requests, the call graphs, service dependencies, process and/or thread monitoring data, etc. The input includes requests, call graphs, service dependencies, process and/or thread monitoring data, etc., and the output of the tracing graph process illustrated in FIG. 4 are application (e.g., database) tracing graphs, which are saved to a database, in one embodiment. In one or more embodiments, call graph builder 404 relates requests-to-services-to-resources, and process graph composer 408 relates processes-to-subprocesses-to-subthreads, with the call graphs and process graphs being used by the database tracing graph builder to compose the tracing graphs.

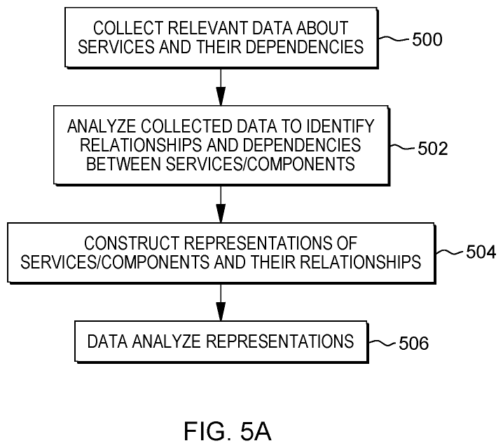

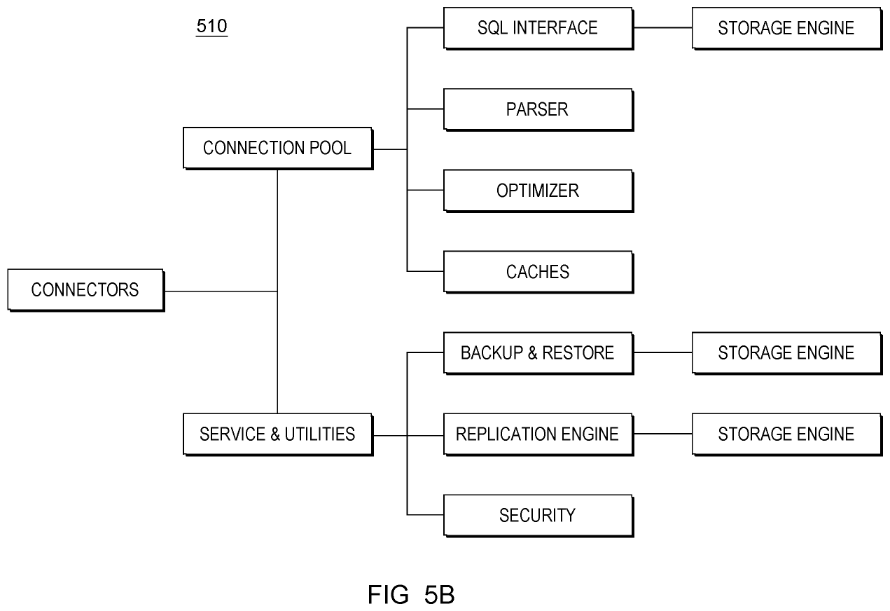

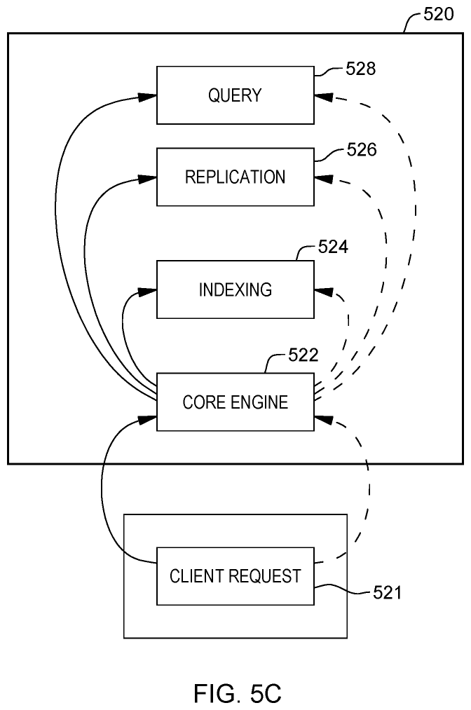

FIG. 5A illustrates one embodiment of database tracing graph builder processing, which as shown includes collecting relevant data about services and their dependencies 500. For instance, relevant data about services and their interactions with a database as a service (DBaaS), and dependent services and/or components are obtained, including system-level metrics, logs, performance monitoring data, or any other information that can facilitate analyzing the services and their dependencies. Further, the process includes analyzing collected data to identify relationships and dependencies between the services and/or components 502. The analyzing identifies relations and dependencies between the services and/or components by examining, for instance, the system call stack, tracing inter-process communication, or analyzing log files. As illustrated in FIG. 5A, the process can further include constructing representations of services and/or components and their relationships 504. In particular, based on the identified dependencies, a graph representation is constructed of the services and/or components and their relationships. Each service can be represented as a node in the graph, and the dependencies between the nodes for processing the request can be represented by edges. One embodiment of a database tracing graph 510 is illustrated in FIG. 5B, where the different components (connectors, connection pool, service & utilities, SQL interface, storage engine, parser, optimizer, caches, backup and restore, replication engine and security) are connected by edges which show dependencies for the request. The representations can then be data-analyzed 506 (FIG. 5A) to perform analysis on the constructed process graph(s) to gain insights into the behavior and dependencies of the request(s) and the related services/components.

As illustrated in FIG. 5C, the enhanced call graphs and the tracing data can be used to construct a database as a service (DBaaS) 520 tracing topology for each database request, such as for a user or a client request 521, which in the example of FIG. 5C, invokes within DBaaS 520, a core engine component 522, an indexing component 524, a replication component 526, and a query component 528, as one example only. This type of topology reflects the flow of interactions and dependencies among the services and/or components involved in processing the particular database request, which can also be represented (by way of example) as follows:

{
“nodes”: [
{
“id”: “core_engine”,
“label”: “Core Engine Service” },
{
“id”: “authentication”,
“label”: “Authentication Service” },
{
“id”: “indexing”,
“label”: “Indexing Service”
},
{
“id”: “logging”,
“label”: “Logging Service”
},
{
“id”: “replication”,
“label”: “Replication Service” },
{
“id”: “query”,
“label”: “Query Service”
}
],
“arrows”: [
{
“source”: “core_engine”,
“target”: “authentication”
},
{
“source”: “core_engine”,
“target”: “indexing”
},
{
“source”: “core_engine”,
“target”: “logging”
},
{
“source”: “core_engine”,
“target”: “replication”
},
{
“source”: “core_engine”,
“target”: “query”
}
]
}

Referring back to FIG. 4, application power consumption determination system 400 further includes, in one or more embodiments, a database request pattern discovery component 422, which has an energy consumption modeler 424 and a request pattern component 426, that operate to associate different request patterns to energy consumption by, for instance, building an association between energy consumption and the generated trace graphs. In one or more embodiments, database request pattern discovery component 422 identifies request pattern models based on application monitoring data and analyzes the historical data to determine common patterns (i.e., common request patterns) and request types, frequencies, and resource usage, to predict and optimize energy consumption for different requests. In one embodiment, inputs include request types, frequencies, and resource usage, etc., such as:

{
“requests”: [
{
“id”: “request1”,
“timestamp”: “2023-07-08 10:30:00”,
“call_graph”: {
“nodes”: [
{
“id”: “service1”,
“label”: “Service 1”
},
{
“id”: “service2”,
“label”: “Service 2”
},
{
“id”: “service3”,
“label”: “Service 3”
}
],
“edges”: [
{
“source”: “service1”,
“target”: “service2”
},
{
“source”: “service2”,
“target”: “service3”
}
]
]
}

With the input, database request pattern discovery component 422 produces discovered patterns or models that represent the behavior or characteristics of the database requests, an example of which is depicted below:

{
“request_patterns”: [
{
“id”: “pattern1”,
“type”: “create, read, update, delete”,
“frequency”: 100,
“energy_estimation”: 500 },
{
“id”: “pattern2”,
“type”: “Query”,
“frequency”: 50,
“energy_estimation”: 300 },
{
“id”: “pattern3”,
“type”: “Replication”,
“frequency”: 20,
“energy_estimation”: 100 }
],
“energy_model”: {
“services”: {
“service1”: {
“energy_consumption”: 50 },
“service2”: {
“energy_consumption”: 100 },
“service3”: {
“energy_consumption”: 80
}
}
}
}

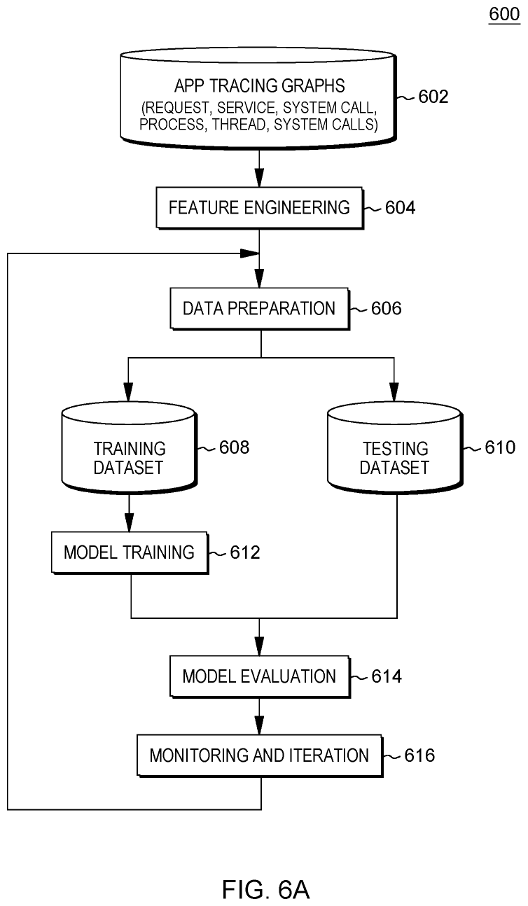

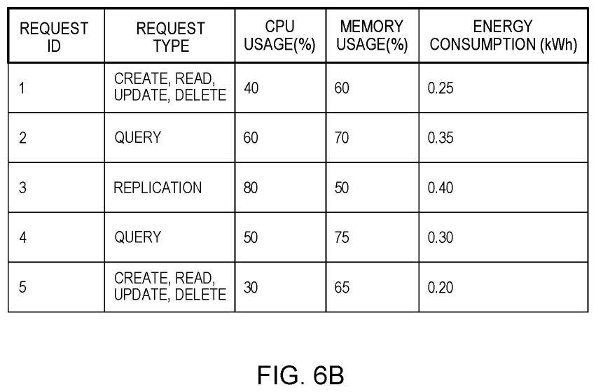

In one or more embodiments, energy consumption modeler 424 trains one or more power consumption models based on the analyzed historical request-related data and simulated request-related data, as well as power consumption data. FIG. 6A depicts one embodiment of a machine learning power consumption model training process, generally denoted 600, in accordance with one or more aspects of the present disclosure. Machine learning power consumption model training process 600 builds one or more power consumption models based on, for instance, the historical data and the simulation data, including the requests, call graphs, service dependencies, process and/or thread monitoring data, and power consumption data, represented by the application tracing graphs 602, such as the database tracing graphs 420 in the embodiment of FIG. 4. The process includes gathering historical data and simulation data on requests, such as database requests, for different users in the application environment, such as a database as a service (DBaaS) application environment. Feature engineering 604 extracts features from the collected data as inputs to an energy estimator model, including, for instance, size of database set of requests, the complexity of the requests, latency of the requests. Data preparation processing 606, in one or more embodiments, splits the obtained data into a training dataset 608 and a testing dataset 610, and further normalizes numerical values and encodes categorical variables. An appropriate machine learning algorithm is selected, such as a regression algorithm or random forest approach, and the model is trained using the training dataset 612. The model can then be evaluated 614 by assessing performance of the trained model using the testing dataset 610. Metrics, such as means-squared-error (MSE), mean-absolute-error (MAE), or coefficient of determination (R²) can be used to gauge how well the model predicts energy consumption for different requests or users, such as individual database users. The energy consumption of the requests can then be predicted for individual users, such as for individual database users. For instance, the relevant input features for a new request can be obtained, and the model can be used to estimate the associated energy consumption based on those features. In one or more embodiments, the training includes monitoring and iteration processing 616, which continuously monitors the performance of the prediction model and collects new data over time. Periodically, the model is retrained as shown using an updated dataset (which includes the collected new data) to improve accuracy and adapt the model to changing request patterns or user behaviors.

By way of example, FIG. 6B illustrates an example training dataset, which can be used to train, for instance, a linear regression model, to estimate power consumption based, for instance, on CPU or memory usage, as an example. The model can be configured to learn the relationship between the independent variables (CPU or memory usage), and the dependent variable (energy consumption). Once trained, the model can be used to estimate energy consumption for new requests based on their CPU and memory usage. By way of example only, a trained energy consumption model in the form of a linear egression equation can be expressed as:

$$Energy Consumption = 0.002 \times CPU Usage + 0.001 \times Memory Usage + 0.1 \qquad ( 1 )$$

Where the coefficients 0.002 and 0.001 represent the weights learned by the model for the CPU and memory usage, respectively, and the constant term 0.1 represents any baseline energy consumption not accounted for by CPU and memory usage.

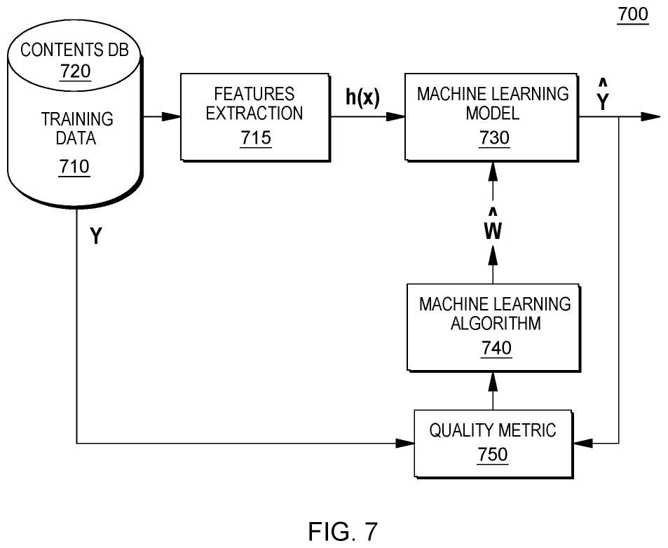

By way of further example, FIG. 7 is one embodiment of a machine learning training process and system 700 that may be utilized, in one or more aspects, to perform training of a machine learning power consumption model based on historical request-related data, and in one or more embodiments, based on request-related simulation data, such as described herein. Training data utilized to train the model in one or more embodiments of the present disclosure includes, for instance, data that pertains to one or more requests, such as actual historical request data, and synthetically generated or simulated data, etc. The program code in embodiments of the present disclosure performs a cognitive analysis to generate one or more training data structures, including algorithms utilized by the program code to predict or estimate power consumption requests. Machine learning (ML) solves problems that are not solved with numerical means alone. In this ML-based example, program code extracts various attributes from ML training data 710 (e.g., historical request-related data and/or simulation data, and power consumption data collected from one or more data sources) which may be resident in one or more databases 720 containing request-related data and power consumption data. Attributes 715 are extracted and utilized to develop a predictor function, h (x), also referred to as a hypothesis, which the program code utilizes as a machine learning model 730.

In identifying various states, features, constraints, and/or behaviors indicative of states in the ML training data 710, the program code can utilize various techniques to identify attributes in an embodiment of the present disclosure. Embodiments of the present disclosure utilize varying techniques to select attributes (elements, patterns, features, constraints, etc.), including, but not limited to, diffusion mapping, principal component analysis, recursive feature elimination (a brute force approach to selecting attributes), and/or a Random Forest, to select the attributes related to various requests. The program code may utilize one or more machine learning algorithms 740 to train the machine learning model 730 (e.g., the algorithms utilized by the program code), including providing weights for the conclusions, so that the program code can train the predictor functions that comprise the machine learning model 730. The conclusions may be evaluated by a quality metric 750. By selecting a diverse set of ML training data 710, the program code trains the machine learning model 730 to identify and weight various attributes (e.g., features, patterns, constraints) that correlate to various states of request processing.

Referring back to FIG. 4, application power consumption determination system 400 receives real-time database requests and/or calls, and operational data 441 at a database request analyzer 440. In one or more embodiments, database request analyzer 440 includes a request/call classifier 442 and an application tracing graph composer 444 which operate to profile incoming database requests (i.e., requests and/or calls) based on real-time application operation data (e.g., monitoring data, log data, etc.). In one or more embodiments, database request analyzer 440 analyzes incoming requests and determines the request type and tracing graph for use in predicting or measuring the corresponding power consumption of the computing environment resources in handling the requests. The input includes incoming requests (or calls) using real-time application operation data, such as monitoring metrics and logs, and the output provides fine-grained information about the characteristics and resource requirements of each request type.

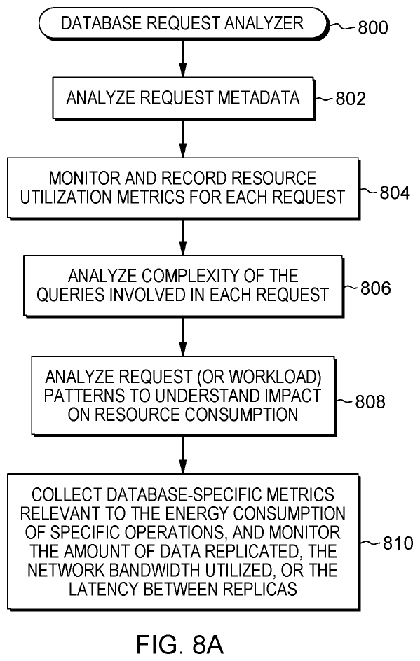

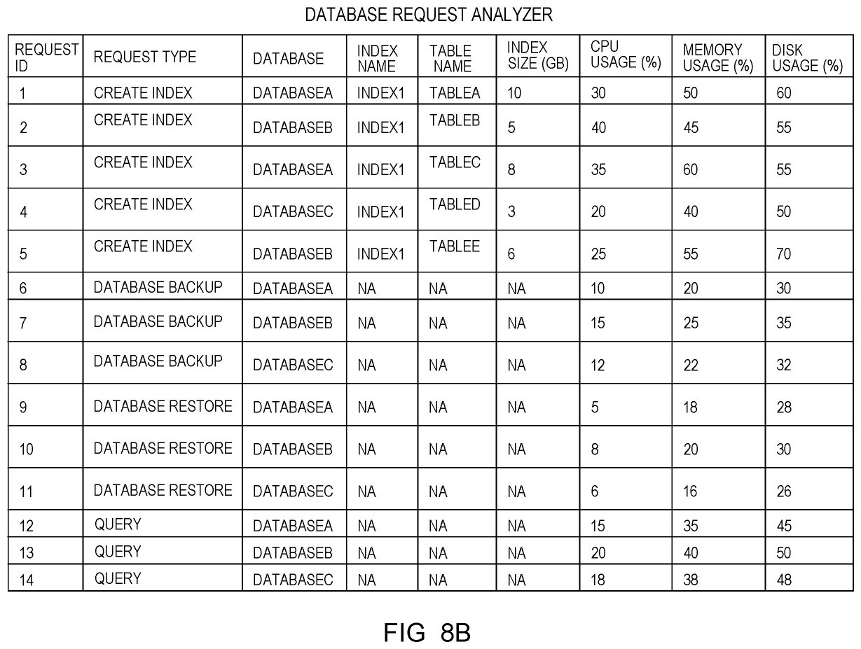

FIG. 8A illustrates one embodiment of a database request analyzer workflow 800, which includes analyzing request metadata 802 to obtain, for instance, the type of request (e.g., create, read, update, delete), index-related, replication, restore, the database that is being targeted, the requesting user, and any other relevant contextual information. The database request analyzer monitors and records resource utilization metrics for each request 804. For instance, metrics, such as CPU usage, memory consumption, disk input/output, network traffic, and other relevant performance indicators, can be monitored and recorded. An example of the database request analysis is depicted below:

{
“request_id”: “987654321”,
“request_type”: “Index Creation”,
“database”: “mydatabase”,
“collection”: “products”,
“index_name”: “price_index”,
“index_fields”: [“price”, “category”],
“tenant”: “tenant2”,
“timestamp”: “2023-07-08T15:30:45Z”,
“resource_utilization”: {
“cpu_usage”: 0.75,
“memory_usage”: 512,
“disk_io”: {
“read_bytes”: 1024,
“write_bytes”: 2048
},
“network_traffic”: {
“incoming”: 750,
“outgoing”: 1000
}
}
}

In the embodiment of FIG. 8A, database request analyzer 800 further analyzes complexity of the queries involved with each request 806, which can include query execution time, number of tables or indices accessed, the size of the resultant set, etc. The database request analyzer process further includes analyzing requests or workload patterns to understand impact on resource consumption 808. The process can include analyzing the frequency, concurrency, and intensity of different request types to understand their impact on resource consumption. As illustrated in FIG. 8A, database-specific metrics relevant to the energy consumption of specific operations are collected, and the processing monitors the amount of data replicated, the network bandwidth utilized, and/or latency between replicas 810.

By way of example, FIG. 8B illustrates one embodiment of collected database-specific metrics relevant to energy consumption, in accordance with one or more aspects of the present disclosure. As illustrated, the collected metrics provide fine-grain information about the characteristics and resource requirements of each request type.

Referring back to FIG. 4, database request analyzer 440 stores the collected database-specific metrics as database request patterns 430 in a database, and provides the information to, in one or more embodiments, a database energy estimator 446, which predicts energy consumption 448 based, for instance, on the machine learning power consumption model, the obtained request pattern, and the collected real-time trace metrics for the particular requests. In one or more embodiments, database request analyzer 440 determines the request type and tracing graph to be used by database energy estimator 446 to determine the corresponding power consumption. The database energy estimator 446, and in particular, predict energy consumption component 448, generates an estimate of the power consumption in addressing a particular request based on the associated request pattern and the application tracing topologies (e.g., database tracing graphs) used to generate or train the machine learning power consumption model.

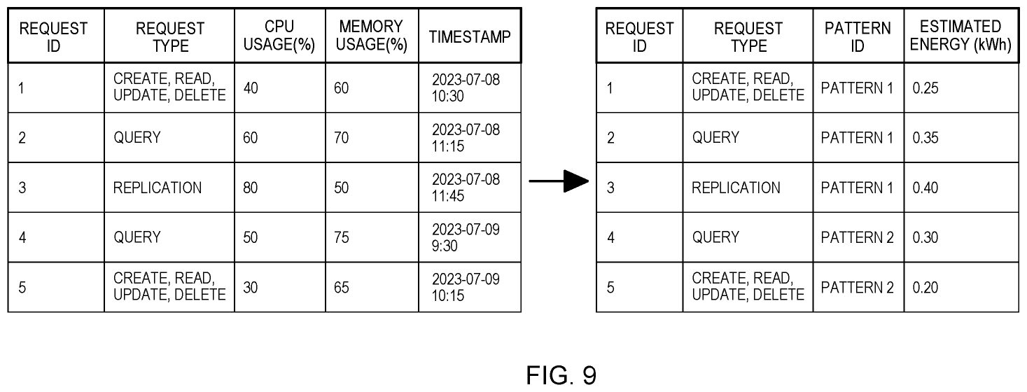

FIG. 9 illustrates one example of input and output data where estimates of power consumption in addressing database requests are obtained, in accordance with one or more aspects of the present disclosure. As illustrated in FIG. 9, the request patterns, application tracing topology, and energy consumption model are used to estimate the energy consumption for each database request (or call). The estimation can be done by assigning energy values to individual services and/or components based on their activity levels in processing a particular request and by aggregating the energy values across the request patterns.

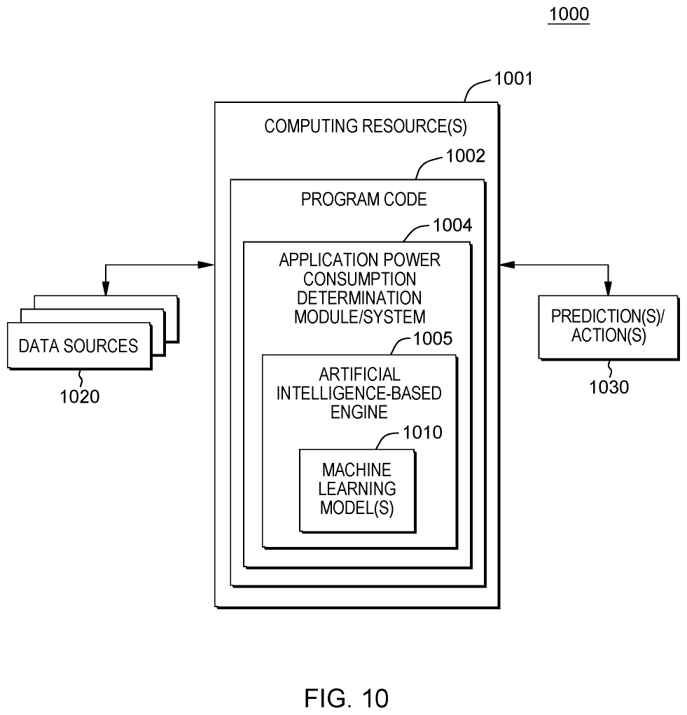

By way of further explanation, FIG. 10 depicts another embodiment of a computing environment or system 1000, which can incorporate, or implement, one or more aspects of an embodiment of the present disclosure. In one or more implementations, system 1000 is implemented as part of a computing environment, such as computing environment 100 described above in connection with FIG. 1. System 1000 includes one or more computing resources 1001 that execute program code 1002 that implements, for instance, one or more aspects of an application energy consumption determination module or system 1004 such as disclosed herein, and which includes an artificial-intelligence-based engine 1005, which can utilize one or more machine learning models 1010, such as described herein. Data, such as historical request-related data and historical power consumption data, as well as simulation data, such as simulated request-related data and simulated request-related power consumption data, and real-time request (or call) data, and other trace metrics, can be used by the artificial-intelligence-based engine (in one embodiment) to train machine learning model(s) 1010 to (for instance) generate an estimate of power consumption addressing one or more requests, and/or to initiate one or more actions based thereon 1030 for the particular application of the machine learning model(s). In one implementation, system 1000 can include, or utilize, one or more networks for interfacing various aspects of computing resource(s) 1001, as well as one or more data sources 1020 providing data, and one or more components, systems, etc., receiving an output, action, etc., 1030 to facilitate performance of one or more operations. By way of example, the network(s) can be, for instance, a telecommunications network, a local-area network (LAN), a wide-area network (WAN), such as the Internet, or a combination thereof, and can include wired, wireless, fiber-optic connections, etc., operatively coupling the computing resource(s) 1001 to the to the data sources. The network(s) can include one or more wired and/or wireless networks that are capable of receiving and transmitting data, including training data for the machine-learning model, and an output solution, recommendation, action, of the machine-learning model(s), such as discussed herein.

In one or more implementations, computing resource(s) 1001 house and/or execute program code 1002 configured to perform methods in accordance with one or more aspects of the present disclosure. By way of example, computing resource(s) 1001 can be a computing-system-implemented resource(s). Further, for illustrative purposes only, computing resource(s) 1001 in FIG. 10 is depicted as being a single computing resource. This is a non-limiting example of an implementation. In one or more other implementations, computing resource(s) 1001 can, at least in part, be multiple separate computing resources or systems, such as one or more computing resources of a cloud-hosting environment, by way of example only.

Briefly described, in one embodiment, computing resource(s) 1001 can include one or more processors, for instance, central processing units (CPUs). Also, the processor(s) can include functional components used in the integration of program code, such as functional components to fetch program code from locations in such as cache or main memory, decode program code, and execute program code, access memory for instruction execution, and write results of the executed instructions or code. The processor(s) can also include a register(s) to be used by one or more of the functional components. In one or more embodiments, the computing resource(s) can include memory, input/output, a network interface, and storage, which can include and/or access, one or more other computing resources and/or databases, as required to implement the machine-learning processing described herein. The components of the respective computing resource(s) can be coupled to each other via one or more buses and/or other connections. Bus connections can be one or more of any of several types of bus structures, including a memory bus or a memory controller, a peripheral bus, an accelerated graphics port, and a processor or local bus, using any of a variety of architectures. By way of example, but not limitation, such architectures can include the Industry Standard Architecture (ISA), the micro-channel architecture (MCA), the enhanced ISA (EISA), the Video Electronic Standard Association (VESA), local bus, and peripheral component interconnect (PCI). As noted, examples of a computing resource(s) or a computer system(s) which can implement one or more aspects disclosed are described further herein with reference to the figures.

In one embodiment, program code 1002 executes application energy consumption determination module/system 1004, including artificial intelligence-based engine 1005, with one or more machine learning models 1010. As noted, the model(s) can be trained using training data that can include a variety of types of data, depending on the model and the data sources. In one or more embodiments, program code 1002 executing on one or more computing resources 1001 applies one or more algorithms of artificial intelligence-based engine 1005 to generate and train the model(s), which the program code then utilizes to, for instance, generate an estimate of power consumption in addressing one or more requests, and/or initiate one or more actions based on generating the estimate of power consumption 1030, based on the particular application of the machine learning model(s). In an initialization or learning stage, program code 1002 trains one or more machine learning models 1010 using obtained training data that can include, in one or more embodiments, one or more data source inputs, such as described.

In one or more embodiments, program code, executing on one or more processors, utilizes an existing cognitive analysis tool or agent (now known or later developed) to tune the model, based on data obtained from one or more data sources. In one or more embodiments, the program code can interface with application programming interfaces to perform a cognitive analysis of obtained data. Specifically, in one or more embodiments, certain application programing interfaces include a cognitive agent (e.g., learning agent) that includes one or more programs, including, but not limited to, natural language classifiers, a retrieve-and-rank service that can surface the most relevant information from a collection of documents, concepts/visual insights, tradeoff analytics, document conversion, and/or relationship extraction. In an embodiment, one or more programs analyze the data obtained by the program code across various sources utilizing one or more of a natural language classifier, retrieve-and-rank application programming interfaces, and tradeoff analytics application programing interfaces.

In one or more embodiments of the present disclosure, the program code can utilize one or more neural networks to analyze training data and/or collected data to generate an operational machine-learning model 1010. Neural networks are a programming paradigm which enable a computer to learn from observational data. This learning is referred to as deep learning, which is a set of techniques for learning in neural networks. Neural networks, including modular neural networks, are capable of pattern (e.g., state) recognition with speed, accuracy, and efficiency, in situations where datasets are mutual and expansive, including across a distributed network, including but not limited to, cloud computing systems. Modern neural networks are non-linear statistical data modeling tools. They are usually used to model complex relationships between inputs and outputs, or to identify patterns (e.g., states) in data (i.e., neural networks are non-linear statistical data modeling or decision-making tools). In general, program code utilizing neural networks can model complex relationships between inputs and outputs and identify patterns in data. Because of the speed and efficiency of neural networks, especially when parsing multiple complex datasets, neural networks and deep learning provide solutions to many problems in multi-source processing, which program code, in embodiments of the present disclosure, can utilize in implementing a machine-learning model, such as described herein.

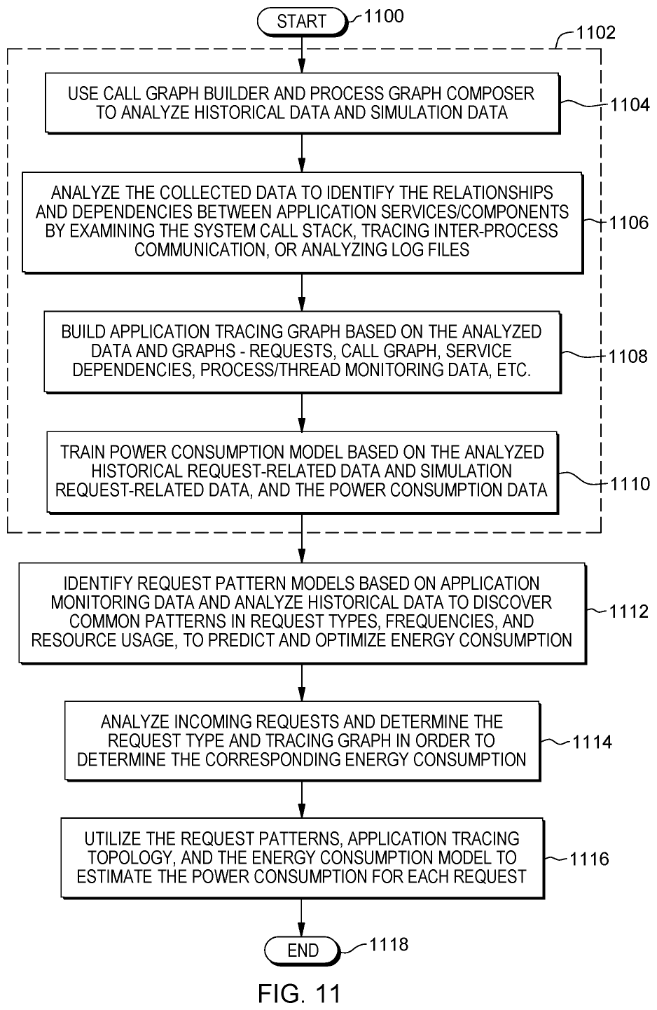

By way of further example, FIG. 11 depicts another embodiment of an application power consumption determination workflow of an application power consumption determination module or system, such as depicted and described above in connection with FIGS. 1-10. The workflow begins 1100 with training 1102 one or more machine learning power consumption models for use in generating an estimate of power consumption in addressing a particular request of an application environment, such as a database as a service (DBaaS) environment. In one or more embodiments, the machine learning power consumption model training 1102 includes using a call graph builder and process graph composer to analyze the historical data and/or simulation data 1104, such as described above in connection with FIGS. 4-9. In addition, the process includes analyzing the collected data to identify relationships and dependencies between application services and/or components by examining, for instance, the system call stack, tracing inter-process communication, and/or analyzing log files 1106. Application tracing graphs are built based on the analyzed data, as well as the call graphs and process graphs, including, for instance, request-related data, call graphs, service dependencies, process and/or thread monitoring data, etc. 1108. The power consumption model is then trained based on the analyzed historical request-related data and (in one embodiment) simulation request-related data, and the power consumption data 1110.

In addition, in one or more embodiments, the application power consumption determination workflow includes identifying request patterns or request pattern models based on application monitored data and analyzing historical data to uncover patterns in request types, frequencies, and resource usage, for use in predicting or estimating power consumption, and therefore, optimizing energy consumption 1112. Further, the workflow includes analyzing incoming requests and determining the request type and tracing graph of each request in order to determine the corresponding energy consumption 1114 and utilizing the request pattern(s), application tracing topology, and the energy consumption model(s) in generating an estimate of the power consumption for one or more requests 1116, which completes the workflow 1118.

In many shared application environments, multiple operations exist, and different access patterns also exist, such as in the case of a database as a service (DBaaS) application. Advantageously, disclosed herein are application power consumption determination modules, systems, and processes which accurately attribute power consumption to different users, or requests of users, to identify, for instance, high energy consumers, and therefore facilitate optimizing resource allocations. Further, an ability to estimate energy consumption for different types of requests is provided, which enables (in one or more embodiments) establishing service level agreements (SLAs) that incorporate power usage considerations. Precise attribution of power consumption allows for better environmental sustainability management. Accurate estimation and attribution of energy consumption also provides transparency to users about their resource usage, and associated costs. In one or more embodiments, computer-implemented methods, computer systems and computer program products are provided for monitoring application energy consumption based on tracing data in, for instance, a database as a service (DBaaS) application. A database request analyzer is provided to profile incoming database requests (or calls) based on real-time application operational data (e.g., monitoring data and/or log data). In one or more embodiments, a call graph builder is provided to build database service call graphs based on services and/or application tracing data, and system call stacks. In one implementation, a process graph analyzer is provided to discover processes and/or threads for a particular request, and dependent services and/or components (such as dependent database services and/or components). In one or more embodiments, a database tracing graph builder is provided to build application tracing topology for each database request (or database call) by infusing system tracing data into the call graphs. Further, in one or more implementations, a request pattern discovery module is provided to discover database request pattern models based on application monitoring data, including using a database energy consumption modeler to build relationships between request patterns and energy costs. Further, in one or more embodiments, an energy estimator is provided to estimate the power consumption based on the request patterns and application tracing topologies, as well as the trained machine learning power consumption model(s).

The terminology used herein is for the purpose of describing particular embodiments only and is not intended to be limiting of the disclosure. As used herein, the singular forms “a”, “and” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements but is not limited to possessing only those one or more steps or elements. Likewise, a step of a method or an element of a device that “comprises”, “has”, “includes” or “contains” one or more features possesses those one or more features but is not limited to possessing only those one or more features. Furthermore, a device or structure that is configured in a certain way is configured in at least that way but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

What is claimed is:

1. A computer-implemented method comprising:
training a machine learning power consumption model to estimate power consumption of computing environment resources in handling requests, the training using a training dataset derived from historical request-related data, wherein the training dataset includes request-related data and resource power consumption data;
analyzing the requests, the analyzing including, for a particular request of the requests, obtaining a common pattern of resource use and collecting real-time trace metrics to facilitate allocating resource use to the particular request; and
using the machine learning power consumption model, the obtained common pattern, and the collected real-time trace metrics for the particular request in generating an estimate of the power consumption in addressing the particular request.

2. The computer-implemented method of claim 1, wherein training the machine learning power consumption model includes training the machine learning power consumption model to associate common patterns of request resource use with the resource power consumption data.

3. The computer-implemented method of claim 1, wherein the requests are requests related to an application of the computing environment, and the training dataset for training the machine learning power consumption model comprises application tracing graphs, the application tracing graphs being obtained, at least in part, from the historical request-related data and historical power consumption data for the application.

4. The computer-implemented method of claim 3, wherein the training dataset is further derived from simulation data including simulated request-related data and simulated resource power consumption data for the application.

5. The computer-implemented method of claim 3, further comprising generating the application tracing graphs from one or more call graphs representative of a hierarchical structure of one or more functions of the application, and from one or more process graphs illustrating relationships and dependencies between different processes of the application, wherein the one or more call graphs and the one or more process graphs are obtained, at least in part, from the historical request-related data.

6. The computer-implemented method of claim 1, wherein the analyzing requests includes determining, for the particular request of the requests, a request type and a corresponding tracing graph, and the using further comprises using the machine learning power consumption model, the obtained common pattern, the request type, the corresponding tracing graph, and the collected real-time trace metrics for the particular request in estimating the power consumption in addressing the particular request.

7. The computer-implemented method of claim 1, further comprising monitoring performance of the machine learning power consumption model, and collecting new request-related data and new resource power consumption data over time, and wherein the computer-implemented method further comprises retraining the machine learning power consumption model using an updated training dataset derived, at least in part, from the historical request-related data, the new request-related data and the new resource power consumption data.

8. The computer-implemented method of claim 1, wherein the requests are requests related to a database as a service (DBaaS) application of the computing environment.

9. The computer-implemented method of claim 1, further comprising initiating an action based on estimating the power consumption of the computing environment resources in addressing the particular request.

10. A computer system comprising:
a memory; and
at least one processor in communication with the memory, wherein the computer system is configured to perform a method, the method comprising:
training a machine learning power consumption model to estimate power consumption of computing environment resources in handling requests, the training using a training dataset derived from historical request-related data, wherein the training dataset includes request-related data and resource power consumption data;
analyzing the requests, the analyzing including, for a particular request of the requests, obtaining a common pattern of resource use and collecting real-time trace metrics to facilitate allocating resource use to the particular request; and
using the machine learning power consumption model, the obtained common pattern, and the collected real-time trace metrics for the particular request in generating an estimate of the power consumption in addressing the particular request.

11. The computer system of claim 10, wherein training the machine learning power consumption model includes training the machine learning power consumption model to associate common patterns of request resource use with the resource power consumption data.

12. The computer system of claim 10, wherein the requests are requests related to an application of the computing environment, and the training dataset for training the machine learning power consumption model comprises application tracing graphs, the application tracing graphs being obtained, at least in part, from the historical request-related data and historical power consumption data for the application.

13. The computer system of claim 12, wherein the training dataset is further derived from simulation data including simulated request-related data and simulated resource power consumption data for the application.

14. The computer system of claim 12, further comprising generating the application tracing graphs from one or more call graphs representative of a hierarchical structure of one or more functions of the application, and from one or more process graphs illustrating relationships and dependencies between different processes of the application, wherein the one or more call graphs and the one or more process graphs are obtained, at least in part, from the historical request-related data.

15. The computer system of claim 10, wherein the analyzing requests includes determining, for the particular request of the requests, a request type and a corresponding tracing graph, and the using further comprises using the machine learning power consumption model, the obtained common pattern, the request type, the corresponding tracing graph, and the collected real-time trace metrics for the particular request in estimating the power consumption in addressing the particular request.

16. The computer system of claim 10, further comprising monitoring performance of the machine learning power consumption model, and collecting new request-related data and new resource power consumption data over time, and wherein the computer-implemented method further comprises retraining the machine learning power consumption model using an updated training dataset derived, at least in part, from the historical request-related data, the new request-related data and the new resource power consumption data.

17. A computer program product comprising:
one or more computer readable storage media and program instructions collectively stored on the one or more computer readable storage media readable by at least one processer to:
train a machine learning power consumption model to estimate power consumption of computing environment resources in handling requests, the training using a training dataset derived from historical request-related data, wherein the training dataset includes request-related data and resource power consumption data;
analyze the requests, the analyzing including, for a particular request of the requests, obtaining a common pattern of resource use and collecting real-time trace metrics to facilitate allocating resource use to the particular request; and
use the machine learning power consumption model, the obtained common pattern, and the collected real-time trace metrics for the particular request in generating an estimate of the power consumption in addressing the particular request.

18. The computer program product of claim 17, wherein training the machine learning power consumption model includes training the machine learning power consumption model to associate common patterns of request resource use with the resource power consumption data.

19. The computer program product of claim 17, wherein the requests are requests related to an application of the computing environment, and the training dataset for training the machine learning power consumption model comprises application tracing graphs, the application tracing graphs being obtained, at least in part, from the historical request-related data and historical power consumption data for the application.

20. The computer program product of claim 19, further comprising generating the application tracing graphs from one or more call graphs representative of a hierarchical structure of one or more functions of the application, and from one or more process graphs illustrating relationships and dependencies between different processes of the application, wherein the one or more call graphs and the one or more process graphs are obtained, at least in part, from the historical request-related data.
